(19) United States
(12) Patent Application Publication
(10) Pub. No.: US 2011/0053097 A1
(43) Pub. Date: Mar. 3, 2011

(54) PROTECTIVE FILM-FORMING MATERIAL AND METHOD OF PHOTORESIST PATTERNING WITH IT

(76) Inventor: Keita ISHIDUKA, Kawasaki-shi (JP)

(21) Appl. No.: 12/870,224

(22) Filed: Aug. 27, 2010

Related U.S. Application Data
(63) Continuation of application No. 12/654,923, filed on Jan. 8, 2010, now abandoned.
Application No. 12/654,923 is a continuation of application No. 12/453,856, filed on May 26, 2009, now abandoned.
Application No. 12/453,856 is a continuation of application No. 11/988,679, now abandoned.

(30) Foreign Application Priority Data
Jul. 12, 2005 (JP) 2005-202565
Feb. 16, 2006 (JP) 2006-040021

(51) Int. Cl. G03F 7/20; C08K 5/06; C08K 5/09

(52) U.S. Cl. 430/325; 524/366; 524/319

(57) ABSTRACT

Problem: Heretofore, when an alcoholic solvent is used alone for a protective film formed as an overlaying layer on a photoresist, there is a problem in that an alcohol-soluble photoresist (for example, negative photoresist) could not be used. The invention solves it, and provides a protective film-forming material which is excellent in its all-purpose utilizability as widely applicable to commercial photoresists and which has basic properties necessary for protective films for use in liquid immersion lithography, and provides a method of photoresist patterning with it.

Means for Solution: A material for forming a protective film to be layered on a photoresist film on a substrate, a protective film-forming material containing (a) an alkali-soluble polymer, and (b) at least one selected from fluoroalkyl ethers and fluoroalkyl esters which do not contain an epoxy ring and in which the hydrogen atoms are partially or wholly substituted with fluorine atoms; and a method of photoresist patterning that uses the protective film-forming material.

### TECHNICAL FIELD

The present invention relates to a protective film-forming material and to a method of photoresist patterning with it. In particular, the invention is favorably applied to a process of liquid immersion lithography.

### BACKGROUND ART

Photography is much used in fabrication of microstructures in various electronic devices such as semiconductor devices, liquid-crystal devices. Recently, the increase in the technical level of large-scale integration and microfabrication is great, and it is desired to further improve the technique of photoresist micropatterning in photolithography.

At present, for example, photolithography in the forefront of the region of high-technology has made it possible to form a photoresist micropattern having a line width of 90 nm or so, and further studies and developments are being made for micropatterning to a higher level to a line width of 65 nm or so.

For attaining micropatterning to such a higher level, in general, some methods of improving photoexposure devices or photoresist materials may be taken into consideration. Regarding the method of improving photoexposure devices, there may be mentioned a method of employing short-wave light sources of F₂ excimer laser, EUV (extreme-ultraviolet ray), electron ray, X ray, soft-X ray, and a method of employing lenses having an increased numerical aperture (NA).

However, the method of employing such short-wave light sources requires an additional expensive photoexposure unit. On the other hand, the method of employing such increased-NA lenses is problematic in that, since the resolution and the focal depth range are in a trade-off relationship, the increase in the resolution may lower the focal depth range.

Recently, liquid immersion lithography has been reported as a technique of photolithography capable of solving these problems (for example, see Non-Patent References 1 to 3). This method is for photoresist patterning through photoexposure of a photoresist film formed on a substrate, in which, in the photoexposure light pathway between the photoexposure device (lens) and the photoresist film, a liquid for liquid immersion lithography having a predetermined thickness is made to be on at least the photoresist film, and the photoresist film is exposed to light in that condition to thereby form a photoresist pattern. In the method of liquid immersion lithography, the photoexposure light pathway space, which is an inert gas such as air or nitrogen in conventional methods, is substituted with a liquid for liquid immersion lithography having a larger refractive index than that of the space (vapor) and having a smaller refractive index (n) than that of the photoresist film (for example, pure water, fluorine-containing inert liquid), and the advantage of the method is that, even though a photoexposure light source having the same wavelength level as that in conventional methods is used therein, the method may attain a high-level resolution like the case that uses a photoexposure light having a shorter wavelength or uses a high-NA lens and, in addition, the method does not result in the reduction in the focal depth range.

To that effect, the process of liquid immersion lithography is much noticed in the art, since it realizes photoresist patterning of high resolution to a good focal depth at low costs, using any lens actually mounted on the existing photoexposure devices therein.

However, in the process of liquid immersion lithography, the photoexposure is attained while a liquid for liquid immersion lithography is made to be on the upper layer of the photoresist film. Naturally, therefore, the method has some problems in that the photoresist film may be deteriorated by the liquid for liquid immersion lithography and the liquid for liquid immersion lithography itself may also be deteriorated by the component dissolved out of the photoresist film whereby the refractive index thereof may vary.

Given that situation, a technique has been proposed which comprises forming a protective film of a fluorine-containing resin on a photoresist film and disposing a liquid for liquid immersion lithography on the protective film, and this is for the purpose of preventing the photoresist film from being deteriorated by the liquid for liquid immersion lithography, preventing the liquid for liquid immersion lithography from being deteriorated and thereby preventing the refractive index thereof from varying (for example, see Patent Reference 1).

Further recently, from the viewpoint of simplifying the step of photoresist patterning and of the production efficiency, a technique of photoresist patterning has become noticed which comprises using a protective film formed of an alkali-soluble polymer so as to remove both the protective film and the unnecessary photoresist film simultaneously during alkali development after liquid immersion lithography.
Non-Patent Reference 1: “Journal of Vacuum Science & Technology B”, USA, 1999, Vol. 17, No. 6, pp. 3306-3309
Non-Patent Reference 2: “Journal of Vacuum Science & Technology B”, USA, 2001, Vol. 19, No. 6, pp. 2353-2356
Non-Patent Reference 3: “Proceedings of SPIE”, USA, 2002, Vol. 4691, pp. 459-465
Patent Reference 1: WO2004/074937 pamphlet

### DISCLOSURE OF THE INVENTION

### Problems that the Invention is to Solve

The material for forming the protective film comprising an alkali-soluble polymer is generally dissolved in an organic solvent in its use, but from the viewpoint of alkali solubility in development, an alcoholic solvent (for example, isobutyl alcohol) is favorably used. When an alcoholic solvent alone is used for conventional protective film-forming materials, then it is not problematic to acrylic positive photoresists (for ArF), but has some negative influences of film thickness reduction, etc., on alcohol-soluble photoresists such as negative photoresists for ArF or KrF, positive photoresists containing a silicon ladder polymer-type resin as the main chain constitutive element, positive photoresists containing a maleic anhydride unit as the main chain constitutive element of resin, and positive photoresists containing a polyhydroxystyrene unit as the constitutive element of the resin component, and therefore it could not attain photoresist patterning and could not apply to such photoresists. Accordingly, a protective film-forming material usable for those alcohol-soluble photoresists is desired. In addition, the protective film must have basic properties necessary for it, including good resistance to the liquid for liquid immersion lithography, low compatibility with the underlying photoresist film, capability of preventing the component of the liquid for liquid immersion lithography from being dissolved out into the photoresist film, capability of preventing the component of the photoresist film from being dissolved out into the liquid for liquid immersion lithography, and capability of preventing vapor penetration through the protective film.

The present invention is to provide a protective film-forming material which solves the above-mentioned prior art problems, which is excellent in its all-purpose utilizability as widely applicable to alcohol-soluble photoresists and which has basic properties necessary for protective films for use in liquid immersion lithography, and to provide a method of photoresist patterning with it.

### Means for Solving the Problems

In order to solve the above-mentioned problems, the invention provides a material for forming a protective film to be layered onto a photoresist film on a substrate, a protective film-forming material containing (a) an alkali-soluble polymer, and (b) at least one selected from fluoroalkyl ethers and fluoroalkyl esters which do not contain an epoxy ring and in which the hydrogen atoms are partially or wholly substituted with fluorine atoms.

The invention also provides a method of photoresist patterning in liquid immersion lithography, which comprises providing a photoresist film on a substrate, forming a protective film onto the photoresist film by the use of the above-mentioned photoresist-protective film-forming material, then disposing a liquid for liquid immersion lithography on at least the protective film of the substrate, thereafter selectively exposing the photoresist film to light through the liquid for liquid immersion lithography and the protective film, then optionally heating it, and developing the protective film and the photoresist film with an alkali developer to thereby remove the protective film and simultaneously obtain a photoresist pattern.

### EFFECT OF THE INVENTION

The invention provides a protective film-forming material which is applicable to alcohol-soluble photoresists and has good all-purpose utilizability as widely applicable to commercially-available photoresists and, in addition, which has basic properties necessary for protective films, including good resistance to liquid for liquid immersion lithography, low compatibility with underlying photoresist film, capability of preventing the component of liquid for liquid immersion lithography from being dissolved out into photoresist film, capability of preventing the component of photoresist film from being dissolved out into liquid for liquid immersion lithography, and capability of preventing vapor penetration through protective film. When the protective film-forming material of the invention is applied to a process of liquid immersion lithography, then it makes it possible to form an ultra-microfabricated photoresist pattern exceeding the resolution in the case of lithography using conventional photoresist materials and photoexposure devices.

### BEST MODE FOR CARRYING OUT THE INVENTION

The invention is described in detail hereinunder.

The protective film-forming material of the invention contains (a) an alkali-soluble polymer, and (b) at least one selected from fluoroalkyl ethers and fluoroalkyl esters which do not contain an epoxy ring and in which the hydrogen atoms are partially or wholly substituted with fluorine atoms.

As the component (a), preferably used is a fluorine-containing alkali-soluble polymer. Concretely, its preferred examples are the following polymers 1 to 4, to which, however, the invention should not be limited.

1. A polymer having a constitutive unit of the following formula (A-1):

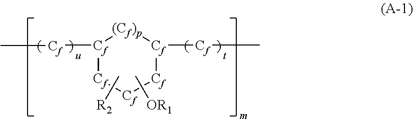

In the above formula (A-1), C_{f} represents —CH₂— (in which the hydrogen atoms may be partially or wholly substituted with fluorine atoms); R₁ represents a hydrogen atom, or a linear-chain, branched-chain or cyclic alkyl group having from 1 to 5 carbon atoms (in which the hydrogen atoms of the alkyl group may be partially or wholly substituted with fluorine atoms); R₂ represents a linear-chain, branched-chain or cyclic alkyl group having from 1 to 5 carbon atoms (in which the hydrogen atoms of the alkyl group may be partially or wholly substituted with fluorine atoms); p, t and u each indicate a number of from 0 to 3; m means a repetitive unit. However, this has a fluorine-substituted group in at least any of C_{f}, R₁ and R₂.

As the alkali-soluble polymer having a constitutive unit of the above formula (A-1), preferred is one having a water-insoluble and alkali-soluble constitutive unit that contains an aliphatic cyclic group having both (A-1-1) a fluorine atom or a fluoroalkyl group, and (A-1-2) an alcoholic hydroxyl group or an oxyalkyl group.

Specifically, the polymer has a constitutive unit (A-1), in which a fluorine atom or a fluoroalkyl group (A-1-1) and an alcoholic hydroxyl group or an alkyloxy group (A-1-2) bond to the aliphatic cyclic group and the cyclic group form the main chain. The fluorine atom or fluoroalkyl group (A-1-1) includes a fluorine atom or a lower alkyl group in which the hydrogen atoms are partially or wholly substituted with fluorine atoms. Concretely, it includes a trifluoromethyl group, a pentafluoroethyl group, a heptafluoropropyl group, a nonafluorobutyl group, but industrially, it is preferably a fluorine atom or a trifluoromethyl group. The alcoholic hydroxyl group or alkyloxy group (A-1-2) may include a hydroxyl group, and the alkyloxy group may be a chain, branched or cyclic alkyloxyalkyl or alkyloxy group having from 1 to 15 carbon atoms.

The alkali-soluble polymer having the unit of the type may be formed through cyclizing polymerization of a diene compound having a hydroxyl group and a fluorine atom. The diene compound is preferably a heptadiene capable of readily forming a 5-membered or 6-membered ring-having polymer having excellent transparency and dry etching resistance. Most preferred is an alkali-soluble polymer formed through cyclic polymerization of 1,1,2,3,3-pentafluoro-4-trifluoromethyl-4-hydroxy-1,6-heptadi ene (CF₂═CFCF₂C(CF₃)(OH)CH₂CH═CH₂).

As specific examples of the polymer having a constitutive unit of the above formula (A-1), preferably used are a polymer containing at least any of constitutive units of the following formulae (A-2) and (A-3), or a copolymer and/or a mixed polymer containing the following formulae (A-2) and (A-3) In the formulae (A-2) and (A-3), R₁ and m have the same meanings as above.

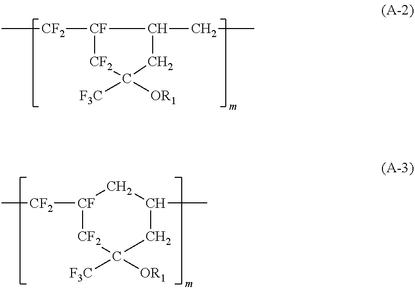

In case where the formulae (A-2) and (A-3) constitute a copolymer and/or a mixed polymer, then it is desirable that they constitute a copolymer and/or a mixed polymer each in a ratio of from 10 to 90 mol %.

2. A polymer having a constitutive unit of the following formula (A-4):

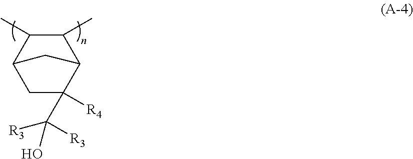

In the above formula (A-4), R₃ represents a linear-chain, branched-chain or cyclic alkyl group having from 1 to 5 carbon atoms (in which the hydrogen atoms of the alkyl group may be partially or wholly substituted with fluorine atoms); R₄ represents a hydrogen atom, a fluorine atom, or a linear-chain, branched-chain or cyclic alkyl group having from 1 to 5 carbon atoms (in which the hydrogen atoms of the alkyl group may be partially or wholly substituted with fluorine atoms); n means a repetitive unit. This has a fluorine-substituted group in at least any of R₃ and R₄.

As specific examples of the constitutive unit of the above formula (A-4), mentioned is a constitutive unit of the following formula (A-4-a) (wherein n has the same meaning as above).

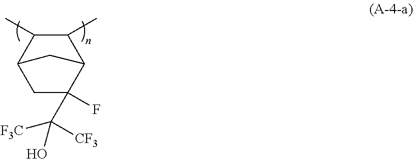

The alkali-soluble polymer containing a constitutive unit of the above formula (A-4) may also be a copolymer and/or a mixed polymer comprising a constitutive unit of the above formula (A-4) and a constitutive unit of the following formula (A-5).

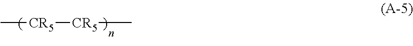

In the above formula (A-5), R₅ represents a hydrogen atom, or a linear-chain, branched-chain or cyclic alkyl group having from 1 to 5 carbon atoms (in which the hydrogen atoms of the alkyl group may be partially or wholly substituted with fluorine atoms); n means a repetitive unit. This has a fluorine-substituted group in at least any of R₅.

As specific examples of the copolymer comprising a constitutive unit of the above formula (A-4) and a constitutive unit of the above formula (A-5), there is mentioned a constitutive component of the following formula (A-6) (wherein n has the same meaning as above).

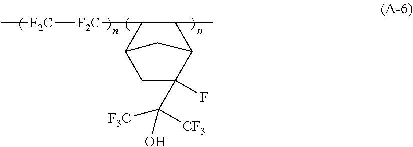

3. A polymer having a constitutive unit of the following formula (A-7):

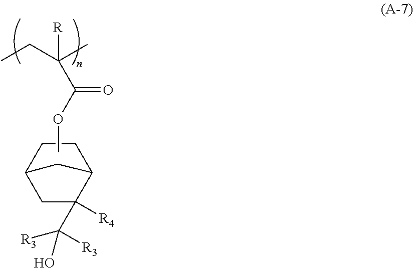

In the above formula (A-7), R₃ represents a linear-chain, branched-chain or cyclic alkyl group having from 1 to 5 carbon atoms (in which the hydrogen atoms of the alkyl group may be partially or wholly substituted with fluorine atoms); R₄ represents a hydrogen atom, a fluorine atom, or a linear-chain, branched-chain or cyclic alkyl group having from 1 to 5 carbon atoms (in which the hydrogen atoms of the alkyl group may be partially or wholly substituted with fluorine atoms); R₄ represents a hydrogen atom or a methyl group; n means a repetitive unit. This has a fluorine-substituted group in at least any of R₃ and R₄.

As specific examples of the constitutive unit of the above formula (A-7), there is mentioned is a constitutive unit of the following formula (A-7-a) (wherein n has the same meaning as above).

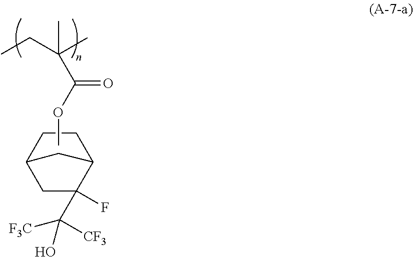

4. A polymer having a constitutive unit of the following formula (A-8):

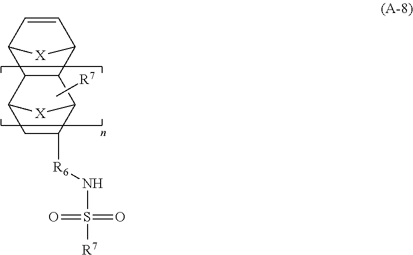

In the above formula (A-8), R₆ represents an alkylene group having from 1 to 6 carbon atoms (in which the hydrogen atoms of the alkylene group may be partially or wholly substituted with fluorine atoms); two R₇'s each independently represent a hydrogen atom, or a linear-chain, branched-chain or cyclic alkyl group having from 1 to 6 carbon atoms (in which the hydrogen atoms of the alkyl group may be partially or wholly substituted with fluorine atoms); X represents an alkylene group having 1 or 2 carbon atoms, or an oxygen atom; n indicates a number of from 0 to 3.

Concretely, R₆ includes a linear-chain alkylene group such as a methylene group, an n-ethylene group, an n-propylene group, an n-butylene group, an n-pentylene group; and a branched-chain alkylene group such as a 1-methylethylene group, a 1-methylpropylene group, a 2-methylpropylene group; and the hydrogen atoms of these alkylene groups may be partially or wholly substituted with fluorine atoms. Of those, preferred is a methylene group.

Concretely, R₇ includes a trifluoromethyl group, a pentafluoroethyl group, a heptafluoropropyl group, a nonafluorobutyl group, a undecafluoropropyl group, a heptadecafluorooctyl group; and the hydrogen atoms of these substituents may be partially or wholly substituted with fluorine atoms. Above all, from the viewpoint of improving hydrophobicity, preferred is a perfluoroalkyl group derived from the substituents by substituting all the hydrogen atoms therein with fluorine atoms; and more preferred is a trifluoromethyl group. Two R₇'s in the formula (A-8) may be the same or different.

Further, X is preferably a methylene group, and n is preferably 0.

The polymer may also be a copolymer comprising a constitutive unit of the above formula (A-8) and at least one constitutive unit selected from monomer units of the following formulae (A-9), (A-10) and (A-11).

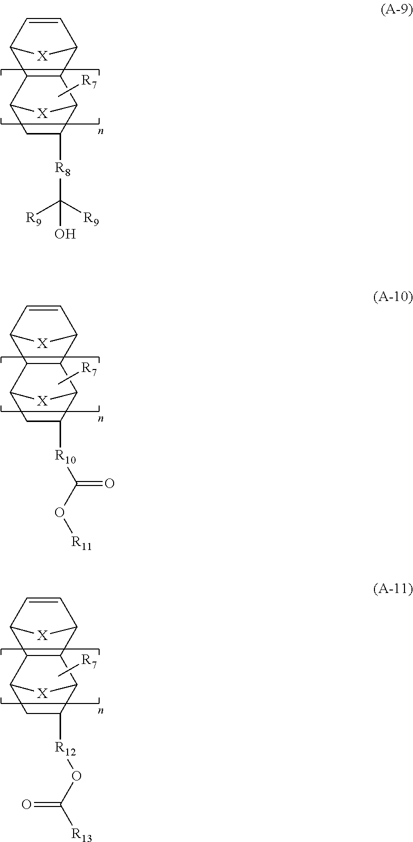

In the above formulae (A-9), (A-10) and (A-11), R₈, R₁₀ and R₁₂ do not exist, or each represent an alkylene group having from 1 to 6 carbon atoms (in which the hydrogen atoms of the alkylene group may be partially or wholly substituted with fluorine atoms); R₉, R₁₁ and R₁₃ each represent a linear-chain, branched-chain or cyclic alkyl group having from 1 to 15 carbon atoms (in which a part of the alkyl group may be via an ether bond, and the hydrogen atoms of the alkyl group may be partially or wholly substituted with hydroxyl groups and fluorine atoms); R7, X and n have the same meanings as in the above formula (A-8).

The monomer unit of the above formula (A-9) is preferably a monomer unit of the following formula (A-12):

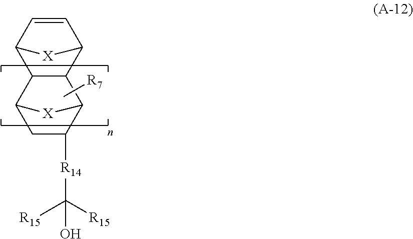

In the above formula (A-12), R₁₄ does not exist, or is a methylene group; R₁₅ is a methyl group or a perfluoromethyl group. Preferably, X is a methylene group, and n is preferably 0.

The monomer unit of the above formula (A-10) is preferably a monomer unit of the following formula (A-13):

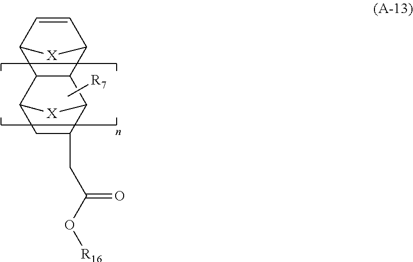

In the above formula (A-13), R₁₆ represents a linear-chain or branched-chain alkyl group having from 2 to 10 carbon atoms (in which the hydrogen atoms of the alkyl group may be partially or wholly substituted with hydroxyl groups and fluorine atoms); R₇, X and n have the same meanings as in the above formula (A-8). In particular, R₁₆ is preferably a substituent selected from —CH₂C₂F₆ or —C(CH₃)CH₂C(CF₃)₂OH.

The monomer unit of the above formula (A-11) is preferably a monomer unit of the following formula (A-14):

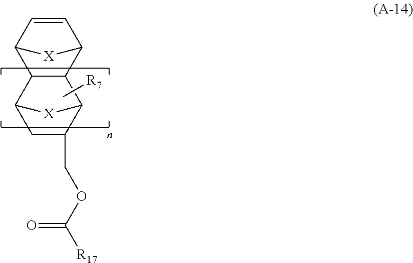

In the above formula (A-14), R₁₇ represents a linear-chain or branched-chain alkyl group having from 5 to 10 carbon atoms (in which the hydrogen atoms of the alkyl group may be partially or wholly substituted with hydroxyl groups and fluorine atoms); R₇, X and n have the same meanings as in the above formula (A-8). In particular, R₁₇ is preferably a substituent selected from —C₇F₁₅, —CF₂CF(CF₃)CF₂CF₂CF₂CF(CF₃)₂, or —CF₂CF(CF₃)CF₂C(CF₃)₃.

In case where the copolymer is used, the constitutive ratio (molar ratio) of the monomer unit of the above formula (A-8) to at least one selected from the monomer units of the above formulae (A-9), (A-10) and (A-11) therein is preferably from 60:40 to 99:1.

The component (a) may be a homopolymer obtained through polymerization of the constitutive unit (monomer unit) of the above formulae, or may also be a copolymer obtained through copolymerization of those monomer units and any other monomer unit within a range not detracting from the above-mentioned characteristics necessary for protective film-forming materials.

The component (a) for use herein preferably has a polystyrene-based mass-average molecular weight by GPC of from 2,000 to 80,000 or so, more preferably from 3,000 to 50,000 or so, to which, however, the invention should not be limited.

The blend ratio of the component (a) is preferably from 0.1 to 20% by mass or so of the overall amount of the protective film-forming material (containing the component (b) as a solvent to be described below), more preferably from 0.3 to 5% by mass.

The component (a) may be produced according to a known polymerization method for alkali-soluble polymer.

The protective film-forming material of the invention contains, as the indispensable ingredients, an organic solvent as a component (b) in addition to the above-mentioned component (a).

As the component (b), herein used is at least one selected from fluoroalkyl ethers and fluoroalkyl esters which do not contain an epoxy ring and in which the hydrogen atoms are partially or wholly substituted with fluorine atoms. Preferably, the fluoroalkyl ethers and fluoroalkyl esters are those having from 4 to 15 carbon atoms.

The preferred fluoroalkyl ethers may be represented by a formula, RCOOR′ (R and R′ each represent an alkyl group, and the total of the carbon atoms constituting the two alkyl groups is from 4 to 15, and the hydrogen atoms thereof are partially or wholly substituted with fluorine atoms).

The preferred fluoroalkyl ethers may be represented by a formula, RCOOR′ (R and R′ each represent an alkyl group, and the total of the carbon atoms constituting the two alkyl groups is from 3 to 14, and the hydrogen atoms thereof are partially or wholly substituted with fluorine atoms).

Preferred examples of the fluoroalkyl ethers for the component (b) are compounds of the following formulae (B-1) and (B-2), to which, however, the invention should not be limited.

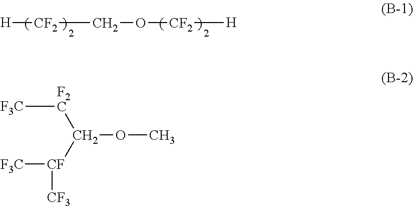

Preferred examples of the fluoroalkyl esters for the component (b) are compounds of the following formulae (B-3) and (B-4), to which, however, the invention should not be limited.

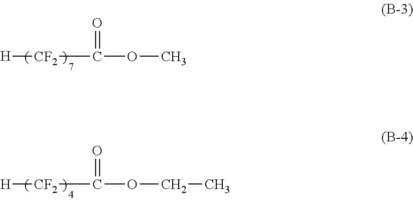

The blend ratio of the component (b) is preferably so controlled that the protective film-forming material could be a solution having a concentration of from 0.1 to 20% by mass, more preferably from 0.3 to 5% by mass.

Comprising a combination of the above component (a) and component (b), the protective film-forming material of the invention makes it possible to use alcohol-soluble photoresists such as negative photoresists for ArF or KrF, positive photoresists containing a silicon ladder polymer-type resin as the main chain constitutive element, positive photoresists containing a maleic anhydride unit as the main chain constitutive element of resin, and positive photoresists containing a polyhydroxystyrene unit as the constitutive element of the resin component, which heretofore could not be used when an alcohol solvent is used alone for them.

However, within a range not detracting from the effect of the resist protective film-forming material of the invention, concretely within a range not having any negative influences of film thickness reduction, etc., on alcohol-soluble photoresists that may be often problematic when the above-mentioned alcohol solvent alone is used for them, any other organic solvent than those mentioned in the above may be further incorporated in the material.

The organic solvent includes an alcoholic solvent having from 1 to 10 carbon atoms, concretely, it is preferably an alcoholic solvent, such as n-butyl alcohol, isobutyl alcohol, n-pentanol, 4-methyl-2-pentanol, and 2-octanol. The hydrogen atoms constituting the alcoholic solvent may be partially substituted with fluorine atoms.

The organic solvent may be incorporated in the material within a range not detracting from the effect of the invention; and concretely, it may be incorporated in an amount of up to 80% by mass as its uppermost limit of the overall amount of the solvent.

The protective film-forming material of the invention may further contain an acid substance, especially a fluorocarbon compound as a component (c). Containing the component (c), the material may have an effect of improving the profile of photoresist patterns.

Preferred examples of the component (c) are, for example, fluorocarbon compounds of the following formula (C-1):

(CᵣF₂ᵣ₊₁SO₂)₂NH (C-1)

[in the formula (C-1), r indicates an integer of from 1 to 5], fluorocarbon compounds of the following formula (C-2):

CₛF₂ₛ₊₁COOH(C-2)

[in the formula (C-2), s indicates an integer of from 10 to 15], fluorocarbon compounds of the following formula (C-3):

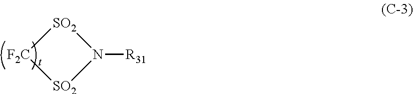

[in the formula (C-3), t indicates an integer of 2 or 3, R₃₁ represents an alkyl group in which the hydrogen atoms are partially or wholly substituted with fluorine atoms and in which the other hydrogen atoms may be partially substituted with a hydroxyl group, an alkoxy group, a carboxyl group or an amino group], fluorocarbon compounds of the following formula (C-4):

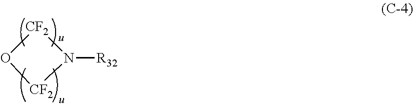

[in the formula (C-4), u indicates an integer of 2 or 3, R₃₂ represents an alkyl group in which the hydrogen atoms are partially or wholly substituted with fluorine atoms and in which the other hydrogen atoms may be partially substituted with a hydroxyl group, an alkoxy group, a carboxyl group or an amino group]; however, the invention should not be limited to these examples. Significant New Use Rule (SNUR) does not apply to these fluorocarbon compounds, and any one can use them.

Examples of the fluorocarbon compounds of the above formula (C-1) are (C₄F₉SO₂)₂NH, (C₃F₇SO₂)₂NH.

An example of the fluorocarbon compounds of the above formula (C-2) is C₁₀F₂₁COOH.

An example of the fluorocarbon compounds of the above formula (C-3) is a compound of the following formula (C-5):

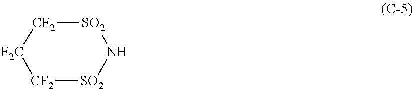

An example of the fluorocarbon compounds of the above formula (C-4) is a compound of the following formula (C-6):

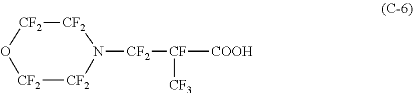

When the component (c) is added to the material, then its amount is preferably from 0.1 to 10% by mass or so of the amount of the above component (a).

The photoresist protective film-forming material of the invention may further contain (d) a crosslinking agent.

For the component (d), preferred for use herein is a nitrogen-containing compound which has an amino group and/or an imino group and in which at least two hydrogen atoms are substituted with a hydroxyalkyl group and/or an alkoxyalkyl group. The nitrogen-containing compound of the type includes, for example, melamine derivatives, urea derivatives, guanamine derivatives, acetoguanamine derivatives, benzoguanamine derivatives and succinylamide derivatives in which the hydrogen atom of the amino group is substituted with a methylol group or an alkoxymethyl group or with both of the two; as well as glycoluryl derivatives and ethylene-urea derivatives in which the hydrogen atom of the imino group is substituted.

These nitrogen-containing compounds may be obtained, for example, by reacting a melamine derivatives, an urea derivative, a guanamine derivative, an acetoguanamine derivative, a benzoguanamine derivative, a succinylamide derivative, a glycoluryl derivative or an ethylene-urea derivative with formalin in boiling water to thereby methylolate the derivative, or by further reacting it with a lower alcohol, concretely methanol, ethanol, n-propanol, isopropanol, n-butanol or isobutanol to thereby alkoxylate it.

The component (d) for use herein is more preferably tetrabutoxymethylated glycoluryl.

As the component (d), also preferred is a condensation reaction product of at least one type of a hydrocarbon compound substituted with a hydroxyl group and/or an alkoxy group, and a monohydroxy-monocarboxylic acid compound. The monohydroxy-monocarboxylic acid is preferably one in which the hydroxyl group and the carboxyl group bond to one and the same carbon atom or to adjacent two carbon atoms.

When the component (d) is added to the material, its amount is preferably from 0.5 to 10% by mass or so of the amount of the above component (a).

If desired, the protective film-forming material of the invention may further contain any optional surfactant (e) added thereto. The component (e) is, for example, XR-104 (trade name by Dainippon Ink and Chemicals, Inc.), to which, however, the invention should not be limited. Adding the component (e) to the material makes it possible to further improve the coatability of the material and the ability thereof to prevent component release.

When the component (e) is added to the material, its amount is preferably from 0.001 to 10% by mass or so of the amount of the above component (a).

The protective film-forming material of the invention may be produced in any ordinary manner.

The protective film-forming material of the invention is especially favorably used in a process of liquid immersion lithography. The method of liquid immersion lithography is for photoresist patterning through photoexposure of a photoresist film formed on a substrate, in which, in the pathway of the photoexposure light before it reaches the photoresist film, a liquid (liquid for liquid immersion lithography) having a predetermined thickness and having a refractive index larger than that of air but smaller than that of the photoresist film is made to be on at least the photoresist film, and the photoresist film is exposed to light in that condition to thereby form a photoresist pattern having an increased degree of resolution.

For the liquid for liquid immersion lithography, for example, preferred are water (e.g., pure water, deionized water), and fluorine-containing solvents. Above all, from the viewpoint of the optical requirements of the liquid in liquid immersion lithography (in that the refractivity property thereof is good), the easy handlability thereof and the absence of environmental pollution with it, water is the most desirable and is considered as the best.

Using the protective film-forming material of the invention, a protective film may be formed directly onto a photoresist film, and it does not interfere with the patterning photoexposure of the photoresist film. In addition, since the material is insoluble in water, its film may well protect the underlying photoresist film of various compositions during liquid immersion lithography using water, and a photoresist pattern having good characteristics may be obtained. On the other hand, when a photoexposure light having a wavelength of 157 nm (e.g., F₂ excimer laser) is used, then a fluorine-containing medium is considered good as the liquid for liquid immersion lithography for the purpose of reducing the absorption of the photoexposure light by the liquid. Even when such a fluorine-containing solvent is used, the protective film of the invention may sufficiently protect the underlying photoresist film during the process of liquid immersion lithography like in the case of using water as above, and therefore a photoresist pattern having good characteristics may be thereby obtained.

Further, since the protective film-forming material of the invention is soluble in alkali, it is still favorable even in the step of alkali development after the step of photoexposure as it does not require a step of removing the protective film from the photoresist film before the development treatment. In other words, the development of the photoresist film with an alkali developer may be effected while the film still has the protective film thereon. Accordingly, the removal of the protective film and the development of the photoresist film (removal of the unnecessary photoresist film) can be attained at the same time. According to the invention, therefore, a photoresist pattern having a good pattern profile can be fabricated efficiently, without causing environmental pollution and with reducing the number of the necessary steps of the patterning process.

Using the photoresist-protective film-forming material of the invention, a photoresist patterning method in liquid immersion lithography may be carried out, for example, as follows:

First, an ordinary photoresist composition is applied onto a substrate such as a silicon wafer by the use of a spinner or the like, and then pre-baked (PAB treatment) to form a photoresist film thereon. If desired, one layer of an organic or inorganic antireflection film (underlying antireflection film) may be previously formed on a substrate, and then a photoresist film may be formed thereon.

The photoresist composition is not specifically defined, for which is usable any photoresist including negative and positive photoresists developable with an aqueous alkali solution. The photoresist of the type includes, for example, (i) a positive photoresist that contains a naphthoquinonediazide compound and a novolak resin, (ii) a positive photoresist that contains a compound capable of generating an acid through exposure to light, a compound capable of decomposing with an acid to have an increased solubility in aqueous alkali solution, and an alkali-soluble resin, (iii) a positive photoresist that contains a compound capable of generating an acid through exposure to light, and an alkali-soluble resin having a group capable of decomposing with an acid to have an increased solubility in aqueous alkali solution, and (iv) a negative photoresist that contains a compound capable of generating an acid or a radical by light, a crosslinking agent and an alkali-soluble resin, but the invention should not be limited to these.

In particular, the invention has an excellent advantage in that the protective film-forming material is applicable to alcohol-soluble photoresists such as negative photoresists for ArF or KrF, positive photoresists containing a silicon ladder polymer-type resin as the main chain constitutive element, positive photoresists containing a maleic anhydride unit as the main chain constitutive element of resin, and positive photoresists containing a polyhydroxystyrene unit as the constitutive element of the resin component, to which, however, conventional protective film-forming materials could not be applied when an alcohol solvent is used alone for them.

Next, a protective film-forming material of the invention is uniformly applied to the surface of the photoresist film, and then cured by heating to form a protective film.

Next, the substrate with the photoresist film and the protective film formed thereon is immersed in a liquid for liquid immersion lithography.

In that condition, the photoresist film on the substrate is selectively exposed to light through a mask pattern. Accordingly, in this, the photoexposure light passes through the liquid for liquid immersion lithography and through the protective film to reach the photoresist film.

In this step, the photoresist film is kept away from the liquid for liquid immersion lithography by the protective film formed thereon, and is therefore protected from the invasion by the liquid for liquid immersion lithography to be swollen or deteriorated, and on the contrary, the film is prevented from releasing its component into the liquid for liquid immersion lithography to change the optical properties such as the refractivity of the liquid itself for liquid immersion lithography.

The photoexposure light is not specifically defined, for which usable are any radiations such as ArF excimer laser, KrF excimer laser, F₂ excimer laser, EB, EUV, VUV (vacuum ultraviolet ray).

Not specifically defined, the liquid for liquid immersion lithography may be any liquid having a refractive index larger than that of air and smaller than that of the photoresist film used. The liquid for liquid immersion lithography of the type includes, for example, water (pure water, deionized water), and fluorine-containing inert liquids. In addition, also usable herein is a liquid for liquid immersion lithography having high-refractivity characteristics, which may be developed in future. Specific examples of the fluorine-containing inert liquids are liquids comprising, as the principal ingredient thereof, a fluorine-containing compound such as C₃HC₁₂F₅, C₄F₉OCH₃, C₄F₉OC₂H₅, C₅H₃F₇. Of those, preferred is water (pure water, deionized water) from the viewpoint of the cost, the safety, the environmental problem and the wide-range applicability thereof. However, when a photoexposure light having a wavelength of 157 nm (e.g., F₂ excimer laser) is used, then preferred for it is a fluorine-containing solvent from the viewpoint that the absorption of the photoexposure light by the solvent is small.

After the step of photoexposure of the photoresist film kept immersed in the liquid as above, the substrate is taken out of the liquid for liquid immersion lithography, and then the liquid is removed from the substrate.

Next, while the protective film is still on the exposed photoresist film, the photoresist film is subjected to PEB (post-exposure baking) and then developed with an alkali developer comprising an aqueous alkali solution. The alkali developer may be any ordinary one. As a result of the alkali development treatment, the protective film is dissolved and removed along with the soluble part of the photoresist film. After the development, the substrate may be post-baked. Subsequently, this is rinsed with pure water or the like. The rinsing with water may be effected, for example, as follows: While the substrate is rotated, water is dropped or sprayed onto the surface of the substrate so that the developer and the protective film component and the photoresist composition having been dissolved by the developer are washed away. Then, this is dried, and a photoresist pattern is thus formed thereon on which the photoresist film is patterned in accordance with the profile of the mask pattern used. Accordingly, in the invention, the removal of the protective film and the development of the photoresist film are attained simultaneously in the development step. The protective film formed of the protective film-forming material of the invention has an increased degree of water repellency, and therefore it may well repel the liquid for liquid immersion lithography after the exposure step, or that is, the amount of the liquid still adhering to the protective film after the step is small and the leakage of the liquid for liquid immersion lithography may be reduced.

In that manner, a photoresist pattern is formed in the invention. Thus formed, the photoresist pattern has a microstructure of good resolution, and in particular it may be a line-and-space pattern having a small pitch. The pitch of the line-and-space pattern as referred to herein means the total distance of the photoresist pattern width and the space width in the line width direction of the pattern.

According to the invention, there is obtained a protective film-forming material which is excellent in its all-purpose utilizability as widely applicable to commercially-available photoresists (especially to alcohol-soluble photoresists), which has good solubility in alcoholic solvents and others, and which has basic properties necessary for protective films for use in liquid immersion lithography, including good resistance to the liquid for liquid immersion lithography, low compatibility with the underlying photoresist film, capability of preventing the component of the liquid for liquid immersion lithography from being dissolved out into the photoresist film, capability of preventing the component of the photoresist film from being dissolved out into the liquid for liquid immersion lithography, and capability of preventing vapor penetration through the protective film.

### EXAMPLES

The invention is described in more detail with reference to the following Examples, to which, however, the invention should not be limited.

In the following Examples, the solvent to be incorporated in the protective film-forming material (hereinafter this may be simply referred to as “protective film solvent”), the alkali-soluble polymer and the photoresist mean those of the following compositions, unless otherwise specifically indicated.

### <Protective Film Solvent>

Comparative Solvent 1: isobutyl alcohol,
Comparative Solvent 2: epoxide solvent of the following formula (Z-1),
Comparative Solvent 3: epoxide solvent of the following formula (Z-2),
Solvent 1: fluoroalkyl ester (component (b)) of the above formula (B-3),
Solvent 2: fluoroalkyl ester (component (b)) of the above formula (B-4),
Solvent 3: fluoroalkyl ether (component (b)) of the above formula (B-1),
Solvent 4: fluoroalkyl ether (component (b)) of the above formula (B-2).

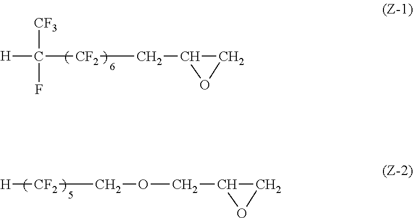

### <Photoresist>

Photoresist 1: positive acrylic photoresist (“TARF-P6111ME”, by Tokyo Ohka Kogyo, Co., Ltd.),
Photoresist 2: negative photoresist (“TARF-N400PE”, by Tokyo Ohka Kogyo, alcohol-soluble photoresist),
Photoresist 3: (silicon-base) positive photoresist containing a silicon ladder polymer resin as the main chain constitutive element (“TARF-SC123”, by Tokyo Ohka Kogyo, Co., Ltd.).

### <Alkali-Soluble Polymer>

Polymer 1: polymer comprising a constitutive unit of the above formula (A-2) (where R₁ is a hydrogen atom) (Mw=5,000) (component (a)),
Polymer 2: polymer comprising a constitutive unit of the above formula (A-6) (where the number of two repetitive units, i.e., n=50) (Mw=4,000) (component (a)).

### 1. Evaluation of Physical Properties of Developer-Soluble Protective Film:

### Example 1

The influence of protective film solvent on photoresist (in point of the presence or absence of photoresist film thickness reduction) was investigated according to the following evaluation method.

Specifically, a photoresist film was formed on a substrate by spin coating, and then baked at 90° C. for 90 seconds. Next, each protective film solvent was applied onto the photoresist film, then after 3 seconds, this was spin-dried. Before and after the application of the protective film solvent, the thickness of the photoresist film was measured, and the influence was evaluated. The results are shown in Table 1.

TABLE 1

| | Influence of Protective Film Solvent on Photoresist | | | |
|---|---|---|---|---|
| | (film thickness reduction) | | | |
| | Photoresist 1 | | Photoresist 2 | |
| | Photoresist | Photoresist | Photoresist | Photoresist |
| | Film Thickness | Film Thickness | Film Thickness | Film Thickness |
| | (before | (after solvent | (before | (after solvent |
| | solvent application) | application) | solvent application) | application) |
| Comparative | 228 nm | 226 nm | 171 nm | 0 nm |
| Solvent 1 | | | | |
| Comparative | (could not be dried on | | — | |
| Solvent 2 | photoresist) | | | |
| Comparative | (could not be dried on | | — | |
| Solvent 3 | photoresist) | | | |
| Solvent 1 | 229 nm | 229 nm | 171 nm | 173 nm |
| Solvent 2 | 229 nm | 229 nm | 170 nm | 172 nm |
| Solvent 3 | 229 nm | 229 nm | 170 nm | 170 nm |

### Example 2

The ability of the protective film solvent to dissolve the alkali-soluble polymer was evaluated according to the following evaluation method.

Specifically, each alkali-soluble polymer was dissolved in the protective film solvent to have a polymer concentration of 2.0% by mass, whereupon the polymer was visually checked for its solubility and evaluated. The results are shown in Table 2.

TABLE 2

Solubility of Alkali-Soluble Polymer in
Protective Film Solvent

| | Polymer 1 | Polymer 2 |
|---|---|---|
| Comparative Solvent 1 | soluble | soluble |
| Solvent 1 | soluble | soluble |
| Solvent 2 | soluble | soluble |

In place of the alkali-soluble polymer, the resin (base polymer) in the photoresist was tested for the solubility thereof in the protective film solvent in the same manner as above. As the base polymer, used was a polymer having a constitutive unit of the following formula (Z-3) (Mw=4,000).

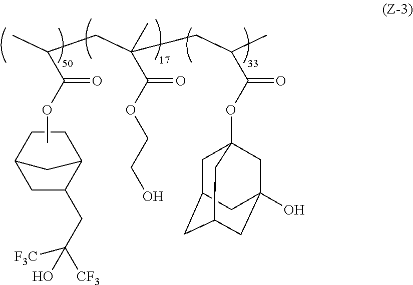

As a result, the above base polymer was soluble in the comparative solvent 1 but was insoluble in the solvents 1 to 3.

### Example 3

The solution prepared in Example 2 was evaluated for its coatability, in the manner mentioned below.

Specifically, the solution prepared in Example 2 was applied onto a substrate by spin coating (1200 rpm), then baked at 90° C. for 60 seconds, and the surface of the protective film was visually checked for the coating condition thereof.

As a result, the solution of the polymer 2 dissolved in the solvent 1, 2 for use in the invention, and the solution of the polymer 1 dissolved in the solvent 2 all had good coatability comparable to or superior to that of the solution of the polymer dissolved in the conventional alcoholic solvent (comparative solvent 1). The solution of the polymer 1 dissolved in the solvent 1 gave some coating mottle, which, however causes no problem in practical use.

### Example 4

The water resistance of the protective film formed in Example 3 was evaluated according to the following evaluation method.

Specifically, the protective film formed in Example 3 was kept in contact with pure water for 120 seconds, and before and after the test, the film thickness change was determined. The results are shown in Table 3.

TABLE 3

| | Resistance to Pure Water of Protective Film | | | |
|---|---|---|---|---|
| | Polymer 1 | | Polymer 2 | |
| | protective | | protective | protective |
| | film | protective | film | film |
| | thickness | film thickness | thickness | thickness |
| | (before | (after | (before | (after |
| | contact with | contact with | contact with | contact with |
| | water) | water) | water) | water) |
| Comparative | 228 nm | 226 nm | 57 nm | 57 nm |
| Solvent 1 | | | | |
| Solvent 1 | 97 nm | 97 nm | 77 nm | 77 nm |
| Solvent 2 | 89 nm | 89 nm | 79 nm | 80 nm |

### Example 5

The presence or absence of the solubility of the protective film formed in Example 3 in developer (whether the film is soluble or insoluble in developer) was evaluated according to the following evaluation method.

Specifically, the substrate having the protective film formed in Example 3 was contacted with an aqueous 2.38 mas·% tetramethylammonium hydroxide (TMAH) solution for 60 seconds, and the film was evaluated for its solubility in alkali developer. The evaluation was attained by determining the protective film thickness change before and after contact with alkali developer.

As a result, the solution of the polymer 1 dissolved in the solvent 1, 2 for use in the invention, and the solution of the polymer 2 dissolved in the solvent 1, 2 all showed good solubility comparable to or superior to that of the solution of the polymer in the conventional alcoholic solvent (comparative solvent 1).

### 2. Resolution Evaluation:

2-1. Liquid Immersion Lithography Evaluation by two-beam interference test:

### <Photoresist>

The following samples were used.

The above photoresist 2 (alcohol-soluble negative photoresist) and photoresist 3 (silicon-base positive photoresist) were used.

### <Protective Film-Forming Material>

The following samples were used.

Sample 1: solution of polymer 1 dissolved in solvent 2 (solid fraction concentration, 2 mas·%),

Sample 2: solution of polymer 2 dissolved in solvent 1 (solid fraction concentration, 2 mas·%),
Sample 3: solution of polymer 2 dissolved in solvent 2 (solid fraction concentration, 2 mas·%),
Sample 4: solution of polymer 2 dissolved in solvent 3 (solid fraction concentration, 2 mas·%),
Sample 5: solution of polymer 1 dissolved in solvent 4 (solid fraction concentration, 2 mas·%),
Comparative Sample 1: solution of polymer 1 dissolved in comparative solvent 1 (solid fraction concentration, 2 mas·%),

### Example 6

An organic antireflection film composition “ARC29” (by Brewer) was applied onto a silicon wafer with a spinner, and baked and dried on a hot plate at 225° C. for 60 seconds to form an antireflection film having a thickness of 77 nm. The above photoresist 2 was applied onto the antireflection film, and pre-baked and dried on a hot plate at 80° C. for 90 seconds to form a photoresist film having a thickness of 170 nm on the anti-reflection film.

The above sample 1 was applied onto the photoresist film, and heated at 90° C. for 60 seconds to form a protective film having a thickness of 70 nm.

Next, using a laboratory kit for liquid immersion lithography (LEIES 193-1, by Nikon Corp.), the sample was tested for two-beam interference. Pure water was used as the liquid for liquid immersion lithography. Next, this was subjected to PEB treatment at 100° C. for 90 seconds, and then subsequently developed with an aqueous 2.38 mas·% TMAH solution at 23° C. for 60 seconds. In this development step, the protective film was completely removed, and the development of the photoresist film was good.

Thus obtained, the 90-nm line-and-space pattern (1:1) was observed with a scanning electronic microscope (SEM), and the formed line-and-space pattern profile was good.

### Example 7

In Example 6, the sample 2 was used in place of the sample 1, and this was processed in the same manner as in Example 6.

As a result, the protective film was completely removed in the development step, and the development of the photoresist film was good. Thus obtained, the 90-nm line-and-space pattern (1:1) was observed with a scanning electronic microscope (SEM), and the formed line-and-space pattern profile was good.

### Example 8

In Example 6, the sample 3 was used in place of the sample 1, and this was processed in the same manner as in Example 6.

As a result, the protective film was completely removed in the development step, and the development of the photoresist film was good. Thus obtained, the 90-nm line-and-space pattern (1:1) was observed with a scanning electronic microscope (SEM), and the formed line-and-space pattern profile was good.

### Example 9

In Example 6, the sample 4 was used in place of the sample 1, and this was processed in the same manner as in Example 6.

As a result, the protective film was completely removed in the development step, and the development of the photoresist film was good. Thus obtained, the 90-nm line-and-space pattern (1:1) was observed with a scanning electronic microscope (SEM), and the formed line-and-space pattern profile was good.

### Example 10

An organic antireflection film composition “BLC730” (by Tokyo Ohka Kogyo, Co., Ltd.) was applied onto a silicon wafer with a spinner, and baked and dried on a hot plate at 205° C. for 60 seconds to form an antireflection film having a thickness of 250 nm. The above photoresist 3 was applied onto the antireflection film, and pre-baked and dried on a hot plate at 85° C. for 90 seconds to form a photoresist film having a thickness of 100 nm on the anti-reflection film.

The above sample 5 was applied onto the photoresist film, and heated at 90° C. for 60 seconds to form a protective film having a thickness of 70 nm.

Next, using a laboratory kit for liquid immersion lithography (LEIES 193-1, by Nikon Corp.), the sample was tested for two-beam interference. Pure water was used as the liquid for liquid immersion lithography. Next, this was subjected to PEB treatment at 95° C. for 90 seconds, and then subsequently developed with an aqueous 2.38 mas·% TMAH solution at 23° C. for 60 seconds. In this development step, the protective film was completely removed, and the development of the photoresist film was good.

Thus obtained, the 120-nm line-and-space pattern (1:1) was observed with a scanning electronic microscope (SEM), and the formed line-and-space pattern profile was good.

### Comparative Example 1

In Example 6, the comparative sample 1 was used in place of the sample 1, and processing this in the same manner as in Example 6 was tried, however, the photoresist 2 was influenced and dissolved by the comparative sample 1 and a pattern could not be formed.

### Comparative Example 2

The same process as in Example 6 was carried out, in which, however, the sample 1 was not applied (that is, the protective film was not formed).

As a result, the photoresist 2 was influenced and dissolved by the liquid for liquid immersion lithography, and a pattern could not be formed.

2-2. Liquid Immersion Lithography Simulation Evaluation with dry photoexposure device for ArF (=non-liquid immersion photoexposure device):

### <Photoresist>

The above photoresist 1 (positive acrylic photoresist) and photoresist 2 (alcohol-soluble negative photoresist) were used.

### <Protective Film-Forming Material>

The above samples 1, 3 and 4 were used.

### Example 11

An organic antireflection film composition “ARC29” (by Brewer) was applied onto a silicon wafer with a spinner, and baked and dried on a hot plate at 225° C. for 60 seconds to form an antireflection film having a thickness of 77 nm. The above photoresist 2 was applied onto the antireflection film, and pre-baked and dried on a hot plate at 80° C. for 90 seconds to form a photoresist film having a thickness of 170 nm on the anti-reflection film.

The above sample 1 was applied onto the photoresist film, and heated at 90° C. for 60 seconds to form a protective film having a thickness of 70 nm.

Next, this was exposed to light at an exposure intensity of 24.5 mJ/cm², using a photoexposure device for ArF (NSR-S302A by Nikon Corp.). After the exposure, pure water was dropped on it for 1 minute thereby keeping it under a liquid immersion simulation environment. Next, this was subjected to PEB treatment at 100° C. for 90 seconds, and then subsequently developed with an aqueous 2.38 mas·% TMAH solution at 23° C. for 60 seconds. In this development step, the protective film was completely removed, and the development of the photoresist film was good.

Thus obtained, the 130-nm line-and-space pattern (1:1) was observed with a scanning electronic microscope (SEM), and the formed line-and-space pattern profile was good.

### Example 12)

In Example 11, the sample 3 was used in place of the sample 1, and this was processed in the same manner as in Example 11.

As a result, the protective film was completely removed in the development step, and the development of the photoresist film was good. Thus obtained, the 130-nm line-and-space pattern (1:1) was observed with a scanning electronic microscope (SEM), and the formed line-and-space pattern profile was good.

### Example 13

In Example 11, the sample 4 was used in place of the sample 1, and this was processed in the same manner as in Example 11.

As a result, the protective film was completely removed in the development step, and the development of the photoresist film was good. Thus obtained, the 130-nm line-and-space pattern (1:1) was observed with a scanning electronic microscope (SEM), and the formed line-and-space pattern profile was good.

### Example 14

An organic antireflection film composition “ARC29” (by Brewer) was applied onto a silicon wafer with a spinner, and baked and dried on a hot plate at 225° C. for 60 seconds to form an antireflection film having a thickness of 77 nm. The above photoresist 1 was applied onto the antireflection film, and pre-baked and dried on a hot plate at 130° C. for 90 seconds to form a photoresist film having a thickness of 225 nm on the anti-reflection film.

The above sample 1 was applied onto the photoresist film, and heated at 90° C. for 60 seconds to form a protective film having a thickness of 70 nm.

Next, this was exposed to light at an exposure intensity of 20.0 mJ/cm², using a photoexposure device for ArF (NSR-S302A by Nikon Corp.). After the exposure, pure water was dropped on it for 1 minute thereby keeping it under a liquid immersion simulation environment. Next, this was subjected to PEB treatment at 130° C. for 90 seconds, and then subsequently developed with an aqueous 2.38 mas·% TMAH solution at 23° C. for 60 seconds. In this development step, the protective film was completely removed, and the development of the photoresist film was good.

Thus obtained, the 130-nm line-and-space pattern (1:1) was observed with a scanning electronic microscope (SEM), and the formed line-and-space pattern profile was good.

### Example 15

In Example 14, the sample 3 was used in place of the sample 1, and this was processed in the same manner as in Example 14.

As a result, the protective film was completely removed in the development step, and the development of the photoresist film was good. Thus obtained, the 130-nm line-and-space pattern (1:1) was observed with a scanning electronic microscope (SEM), and the formed line-and-space pattern profile was good.

### Example 16

In Example 14, the sample 4 was used in place of the sample 1, and this was processed in the same manner as in Example 14.

As a result, the protective film was completely removed in the development step, and the development of the photoresist film was good. Thus obtained, the 130-nm line-and-space pattern (1:1) was observed with a scanning electronic microscope (SEM), and the formed line-and-space pattern profile was good.

### INDUSTRIAL APPLICABILITY

The protective film-forming material of the invention is applicable to alcohol-soluble photoresists and has good all-purpose utilizability as widely applicable to commercially-available photoresists and, in addition, it has basic properties necessary for protective films (good resistance to liquid for liquid immersion lithography, low compatibility with underlying photoresist film, etc.), and is therefore applicable to a process of liquid immersion lithography. Accordingly, the invention has made it possible to form an ultra-microfabricated photoresist pattern exceeding the resolution in lithography using conventional photoresist materials and photoexposure devices.

1. A material for forming a protective film to be layered on a photoresist film on a substrate, which contains (a) an alkali-soluble polymer, and (b) at least one selected from fluoroalkyl ethers and fluoroalkyl esters which do not contain an epoxy ring and in which the hydrogen atoms are partially or wholly substituted with fluorine atoms.

2. The protective film-forming material as claimed in claim 1, wherein the protective film-forming material is used in a process of liquid immersion lithography.

3. The protective film-forming material as claimed in claim 1, wherein the component (b) is at least one selected from fluoroalkyl ethers and fluoroalkyl esters which have from 4 to 15 carbon atoms and do not contain an epoxy ring and in which the hydrogen atoms are partially or wholly substituted with fluorine atoms.

4. The protective film-forming material as claimed in claim 1, wherein the component (a) is a fluorine-containing alkali-soluble polymer.

5. The protective film-forming material as claimed in claim 1, wherein the component (a) is a polymer having a constitutive unit of the following formula (A-1): 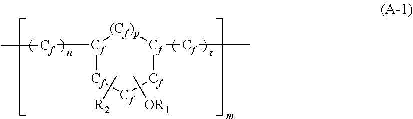
[in the formula (A-1), C_{f} represents —CH₂— (in which the hydrogen atoms may be partially or wholly substituted with fluorine atoms); R₁ represents a hydrogen atom, or a linear-chain, branched-chain or cyclic alkyl group having from 1 to 5 carbon atoms (in which the hydrogen atoms of the alkyl group may be partially or wholly substituted with fluorine atoms); R₂ represents a linear-chain, branched-chain or cyclic alkyl group having from 1 to 5 carbon atoms (in which the hydrogen atoms of the alkyl group may be partially or wholly substituted with fluorine atoms); p, t and u each indicate a number of from 0 to 3; m means a repetitive unit; and this has a fluorine-substituted group in at least any of C_{f}, R₁ and R₂].

6. The protective film-forming material as claimed in claim 5, wherein the polymer having a constitutive unit of the above formula (A-1) is a polymer containing any of constitutive units of the following formulae (A-2) and (A-3), or a copolymer and/or a mixed polymer containing the following formulae (A-2) and (A-3): 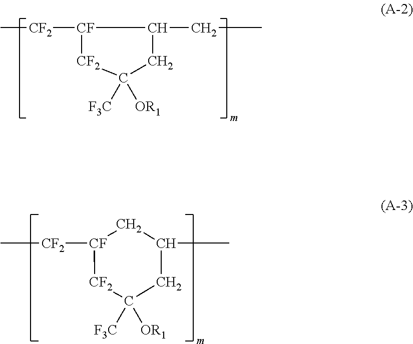
[in the formulae (A-2) and (A-3), R₁ represents a hydrogen atom, or a linear-chain, branched-chain or cyclic alkyl group having from 1 to 5 carbon atoms (in which the hydrogen atoms of the alkyl group may be partially or wholly substituted with fluorine atoms); m means a repetitive unit].

7. The protective film-forming material as claimed in claim 1, wherein the component (a) is a polymer having a constitutive unit of the following formula (A-4): 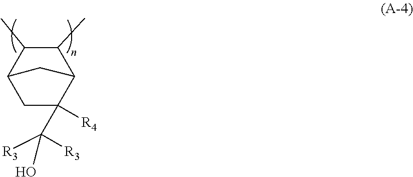
[in the formula (A-4), R₃ represents a linear-chain, branched-chain or cyclic alkyl group having from 1 to 5 carbon atoms (in which the hydrogen atoms of the alkyl group may be partially or wholly substituted with fluorine atoms); R₄ represents a hydrogen atom, a fluorine atom, or a linear-chain, branched-chain or cyclic alkyl group having from 1 to 5 carbon atoms (in which the hydrogen atoms of the alkyl group may be partially or wholly substituted with fluorine atoms); n means a repetitive unit; and this has a fluorine-substituted group in at least any of R₃ and R₄].

8. The protective film-forming material as claimed in claim 7, wherein the component (a) is copolymer and/or a mixed polymer containing a constitutive unit of the above formula (A-4) and a constitutive unit of the following formula (A-5): 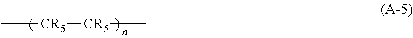
[in the formula (A-5), R₅ represents a hydrogen atom, or a linear-chain, branched-chain or cyclic alkylene group having from 1 to 5 carbon atoms (in which the hydrogen atoms of the alkylene group may be partially or wholly substituted with fluorine atoms); n means a repetitive unit; and this has a fluorine-substituted group in at least any of R₅].

9. The protective film-forming material as claimed in claim 1, wherein the component (a) is a polymer having a constitutive unit of the following formula (A-7): 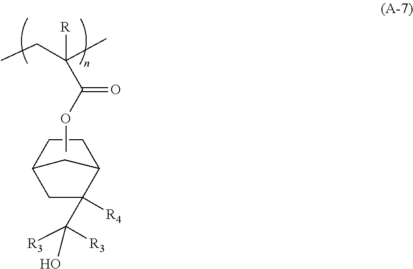
[in the formula (A-7), R₃ represents a linear-chain, branched-chain or cyclic alkyl group having from 1 to 5 carbon atoms (in which the hydrogen atoms of the alkyl group may be partially or wholly substituted with fluorine atoms); R₄ represents a hydrogen atom, a fluorine atom, or a linear-chain, branched-chain or cyclic alkyl group having from 1 to 5 carbon atoms (in which the hydrogen atoms of the alkyl group may be partially or wholly substituted with fluorine atoms); R₃ represents a hydrogen atom or a methyl group; n means a repetitive unit; and this has a fluorine-substituted group in at least any of R₃ and R₄].

10. The protective film-forming material as claimed in claim 1, wherein the component (a) is a polymer having a constitutive unit of the following formula (A-8): 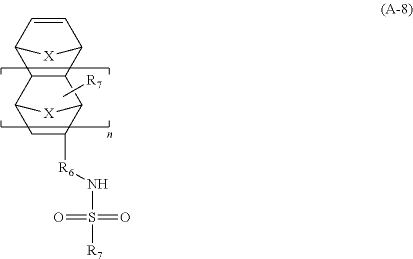
[in the formula (A-8), R₆ represents an alkylene group having from 1 to 6 carbon atoms (in which the hydrogen atoms of the alkylene group may be partially or wholly substituted with fluorine atoms); R₇ represents a hydrogen atom, or a linear-chain, branched-chain or cyclic alkyl group having from 1 to 6 carbon atoms (in which the hydrogen atoms of the alkyl group may be partially or wholly substituted with fluorine atoms); X represents an alkylene group having 1 or 2 carbon atoms, or an oxygen atom; n means a repetitive unit].

11. The protective film-forming material as claimed in claim 1, which further contains an acid substance (c).

12. The protective film-forming material as claimed in claim 11, wherein the component (c) is a fluorocarbon compound.

13. The protective film-forming material as claimed in claim 1, which further contains a crosslinking agent (d).

14. The protective film-forming material as claimed in claim 13, wherein the component (d) is a nitrogen-containing compound which has an amino group and/or an imino group and in which at least two hydrogen atoms are substituted with a hydroxyalkyl group and/or an alkoxyalkyl group.

15. A method of photoresist patterning in liquid immersion lithography, which comprises providing a photoresist film on a substrate, forming a protective film onto the photoresist film by the use of the photoresist-protective film-forming material of claim 1, then disposing a liquid for liquid immersion lithography on at least the protective film of the substrate, thereafter selectively exposing the photoresist film to light through the liquid for liquid immersion lithography and the protective film, then optionally heating it, and developing the protective film and the photoresist film with an alkali developer to thereby remove the protective film and simultaneously obtain a photoresist pattern.
